(19) United States
(12) Patent Application Publication
(10) Pub. No.: US 2026/0165119 A1
(43) Pub. Date: Jun. 11, 2026

(54) STACKED FETS WITH THERMOELECTRIC COOLING

(71) Applicant: INTERNATIONAL BUSINESS MACHINES CORPORATION, Armonk, NY (US)

(72) Inventors: WuKang Kim, Troy, NY (US); Ruilong Xie, Niskayuna, NY (US); Tao Li, Slingerlands, NY (US); Qianwen Chen, Fort Collins, CO (US); Joshua Mark Rubin, Albany, NY (US)

(21) Appl. No.: 18/971,718

(22) Filed: Dec. 6, 2024

(51) Int. Cl. H01L 23/367; H01L 23/00; H01L 25/07

(52) U.S. Cl. CPC H10W 40/22; H10W 90/00; H10W 72/965; H10W 72/967; H10W 90/732

(57) ABSTRACT

Semiconductor devices include a first device layer that includes thermal vias. A second device layer, over the first device layer, has heat transfer pads of different doping types in contact with the thermal vias. A back-end-of-line (BEOL) layer over the second device layer includes a cooling plate and heat transfer structures that connect the heat transfer pads to the cooling plate. A backside power distribution layer is under the first device layer. A cooler is mounted to the backside power distribution layer.

### BACKGROUND

The present invention generally relates to semiconductor devices and, more particularly, to stacked transistors with thermoelectric cooling.

Transistor density can be increased in a semiconductor device by stacking devices over one another. In some cases, entire device layers can be formed over one another, with vias providing electrical interconnection between the layers. However, managing heat that is generated by the transistors can be challenging. If heat cannot be removed quickly enough, the temperature of sensitive components may increase to a point where performance is degraded or permanent damage results.

### SUMMARY

A semiconductor device includes a first device layer that includes thermal vias. A second device layer over the first device layer has heat transfer pads of different doping types in contact with the thermal vias. A back-end-of-line (BEOL) layer over the second device layer includes a cooling plate and heat transfer structures that connect the heat transfer pads to the cooling plate. A backside power distribution layer is under the first device layer. A cooler is mounted to the backside power distribution layer.

A semiconductor device includes a first device layer that includes thermal vias. A second device layer over the first device layer has heat transfer pads of different doping types in contact with the thermal vias. A BEOL layer is over the second device layer. A backside power distribution layer under the first device layer includes a cooling plate and a heat transfer structure that connects the thermal vias to the cooling plate. A cooler is mounted to the BEOL layer.

A semiconductor device includes a first device layer that includes a first device layer that includes heat transfer pads. A second device layer over the first device layer, has thermal vias in contact with the heat transfer pads. A BEOL layer is over the second device layer. A backside power distribution layer under the first device layer includes a cooling plate and heat transfer structures that connect the heat transfer pads to the cooling plate. A cooler is mounted to the BEOL layer.

These and other features and advantages will become apparent from the following detailed description of illustrative embodiments thereof, which is to be read in connection with the accompanying drawings.

### BRIEF DESCRIPTION OF THE DRAWINGS

The following description will provide details of preferred embodiments with reference to the following figures wherein:

FIG. 1 is a cross-sectional view of a step in the fabrication of a multi-layer semiconductor device with thermoelectric cooling, showing the formation of a first layer of transistors on a substrate, in accordance with an embodiment of the present invention;

FIG. 2 is a cross-sectional view of a step in the fabrication of a multi-layer semiconductor device with thermoelectric cooling, showing the formation of a stack of alternating channel and sacrificial layers over the first layer of transistors, in accordance with an embodiment of the present invention;

FIG. 3 is a cross-sectional view of a step in the fabrication of a multi-layer semiconductor device with thermoelectric cooling, showing the formation of a second layer of transistors with materials for thermoelectric heat transfer from the stack of alternating channel and semiconductor layers, in accordance with an embodiment of the present invention;

FIG. 4 is a cross-sectional view of a step in the fabrication of back-end-of-line (BEOL) layers that include heat transfer structures and a cooling plate to remove heat, showing the formation of a first layer of transistors on a substrate, in accordance with an embodiment of the present invention;

FIG. 5 is a cross-sectional view of a step in the fabrication of a multi-layer semiconductor device with thermoelectric cooling, showing the removal of the substrate and sacrificial placeholders underlying the first layer of transistors to expose the undersides of the first layer of transistors, in accordance with an embodiment of the present invention;

FIG. 6 is a cross-sectional view of a step in the fabrication of a multi-layer semiconductor device with thermoelectric cooling, showing the formation of vias through an interlayer dielectric around the first layer of transistors to expose undersides of heat transfer pads, in accordance with an embodiment of the present invention;

FIG. 7 is a cross-sectional view of a step in the fabrication of a multi-layer semiconductor device with thermoelectric cooling, showing the formation of backside contacts and heat transfer vias, in accordance with an embodiment of the present invention;

FIG. 8 is a cross-sectional view of a step in the fabrication of a multi-layer semiconductor device with thermoelectric cooling, showing the formation of backside power distribution layers with a mounted cooler, in accordance with an embodiment of the present invention;

FIG. 9 is a cross-sectional view of an alternative embodiment of a multi-layer semiconductor device with thermoelectric cooling, showing the cold plate being positioned within the backside power distribution layers and the cooler being mounted on an opposite side of the device, in accordance with an embodiment of the present invention;

FIG. 10 is a cross-sectional view of an alternative embodiment of a multi-layer semiconductor device with thermoelectric cooling, showing heat transfer pads being formed within the first layer of transistors, in accordance with an embodiment of the present invention;

FIG. 11 is a block/flow diagram of a method for fabricating a multi-layer semiconductor device with thermoelectric cooling, in accordance with an embodiment of the present invention;

FIG. 12 is a block/flow diagram of a method for fabricating a multi-layer semiconductor device with thermoelectric cooling, in accordance with an embodiment of the present invention; and

FIG. 13 is a block/flow diagram of a method for fabricating a multi-layer semiconductor device with thermoelectric cooling, in accordance with an embodiment of the present invention.

### DETAILED DESCRIPTION

Active and passive cooling can be used to dissipate heat that is generated within the device layers of an integrated circuit. For example, a thermoelectric cooler can be mounted on a side of the integrated circuit to act as a heat pump. However, as the integrated circuit becomes thicker, for example because of stacked device layers, heat generated in farther-away components can have difficulty moving toward the cooler through the intervening layers.

An external cooler may be mounted to either a front side or back side of the semiconductor device. To collect heat from the other side (e.g., from the back side if the cooler is mounted to the front side), a cooling plate may be formed within the back-end-of-line (BEOL) or backside interconnect layers. The cooling plate may be connected by vias to the cooler, providing a channel for heat dissipation through the body of the device. The Peltier effect can be exploited to increase heat transfer from the cooling plate and move it to the external cooler. Thus heat which is generated far from the external cooler may be collected at the cooling plate and may travel through the via structures by the thermoelectric cooler.

Referring now to FIG. 1, a cross-sectional view of a step in the fabrication of a multi-layer semiconductor device with thermoelectric cooling is shown. This cross-section is taken through a device layer that includes transistors, such as field effect transistors (FETs). The cross-section shows source/drain structures of the first components 114 (e.g., FETs), and it should be understood that other parts of the FETs, such as channels and gate stacks, are present but are not shown as they exist outside the plane of the drawing.

An etch stop layer 104 is formed on a semiconductor substrate 102. The etch stop layer 104 may be epitaxially grown from the top surface of the semiconductor substrate 102. A semiconductor remnant 106 is on the etch stop layer 104, left over from the fabrication of components in the device layer.

A set of placeholder structures 112 are embedded in a first dielectric layer 108. The placeholder structures 112 may be formed from a semiconductor material and the first dielectric layer 108 may be formed in a shallow trench isolation (STI) process. A device layer on the first dielectric layer 108 includes a set of first components 114, such as FETs, with an interlayer dielectric 110 around the first components 114.

The semiconductor substrate 102 may be a bulk-semiconductor substrate. In one example, the bulk-semiconductor substrate may be a silicon-containing material. Illustrative examples of silicon-containing materials suitable for the bulk-semiconductor substrate include, but are not limited to, silicon, silicon germanium, silicon germanium carbide, silicon carbide, polysilicon, epitaxial silicon, amorphous silicon, and multi-layers thereof. Although silicon is the predominantly used semiconductor material in wafer fabrication, alternative semiconductor materials can be employed, such as, but not limited to, germanium, gallium arsenide, gallium nitride, cadmium telluride, and zinc selenide.

The etch stop layer 104 may be formed by epitaxial growth from a semiconductor material that has a compatible crystalline structure with the material of the semiconductor substrate. In the case of silicon being used in the semiconductor substrate 102, the etch stop layer 104 may be formed with silicon germanium. The terms “epitaxial growth” and/or “epitaxial deposition” refer to the growth of a semiconductor material on a deposition surface of a semiconductor material, in which the semiconductor material being grown has substantially the same crystalline characteristics as the semiconductor material of the deposition surface. The term “epitaxial material” denotes a material that is formed using epitaxial growth. In some embodiments, when the chemical reactants are controlled and the system parameters set correctly, the depositing atoms arrive at the deposition surface with sufficient energy to move around on the surface and orient themselves to the crystal arrangement of the atoms of the deposition surface. Thus, in some examples, an epitaxial film deposited on a {100} crystal surface will take on a {100} orientation.

Silicon germanium and silicon are selectively etchable with respect to one another. As used herein, the term “selective” in reference to a material removal process denotes that the rate of material removal for a first material is greater than the rate of removal for at least another material of the structure to which the material removal process is being applied. Thus a selective etching process that removes silicon may be impeded by the etch stop layer 104.

The semiconductor remnant 106 may be formed from any appropriate semiconductor material, such as silicon, and may be left over from fabrication of the first components 114. The placeholder structures 112 may similarly be formed from a semiconductor material that is selectively etchable with respect to the semiconductor remnant 106. The first dielectric layer 108 may be formed from any appropriate dielectric, such as silicon dioxide.

The first components 114 may be any appropriate active circuit device, such as FETs (including planar FETs, fin FETs, nanowire FETs, nanosheet FETs, p-type FETs, n-type FETs, junction FETs, etc.) and bipolar junction transistors (BJTs). The device may further include passive components (not shown) such as capacitors, inductors, resistors, antennas, and transmission lines. The interlayer dielectric 110 may be formed around the first components 114 with any dielectric material, such as silicon dioxide or a low-k dielectric. It is specifically contemplated that the first components 114 may include both p-type FETs and n-type FETs, formed by any suitable process with appropriate respective dopants.

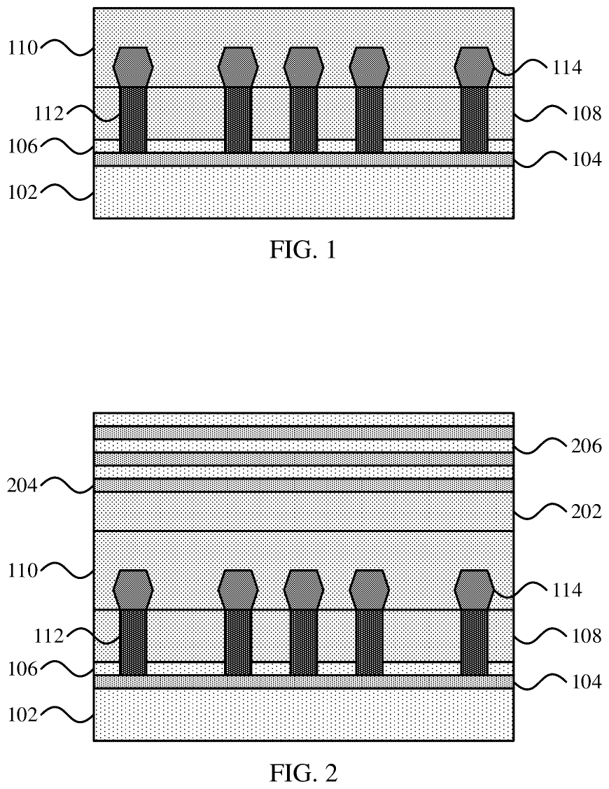

Referring now to FIG. 2, a cross-sectional view of a step in the fabrication of a multi-layer semiconductor device with thermoelectric cooling is shown. A bonding layer 202 is formed on the interlayer dielectric 110 and a stack of semiconductor layers is positioned on the bonding layer 202. The stack of semiconductor layers may include channel layers 206 interleaved with sacrificial layers 204. The channel layers 206 and the sacrificial layers 204 may be formed by epitaxial growth using, e.g., silicon and silicon germanium respectively. The channel layers 206 and sacrificial layers 204 may have respective thicknesses that are below a critical thickness at which discontinuities begin to form as a result of small differences in the crystallographic structures of the respective materials.

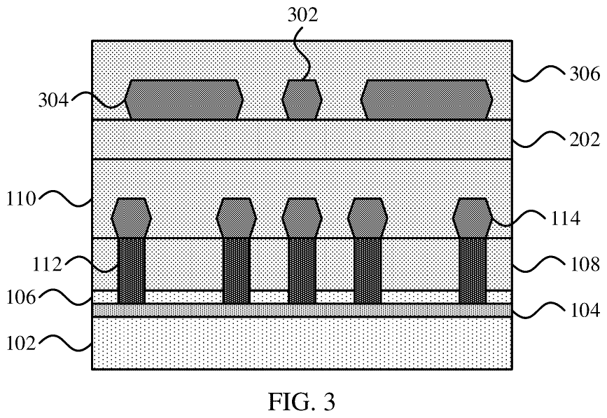

Referring now to FIG. 3, a cross-sectional view of a step in the fabrication of a multi-layer semiconductor device with thermoelectric cooling is shown. The stack of semiconductor layers may be processed to form second components 302 in a second device layer, which may include any appropriate active or passive components. The second components may be formed by a process that includes top dummy gate formation, inner spacer formation, source/drain epitaxial growth, deposition of interlayer dielectric 306, and formation of a replacement metal gate.

Heat transfer pads 304 may also be formed as part of the process of forming the second components 302. Thus the heat transfer pads 304 may include an n-doped or p-doped semiconductor material that is epitaxially grown. To cool the devices, the heat transfer pads 304 may be formed with semiconductor materials having differing dopant types, such as n-doped semiconductor and p-doped semiconductor materials, which may be connected to Vss and Vdd, respectively, to induce the Peltier effect. Also, materials for the heat transfer pads 304 could be any material that can yield to Peltier effect, such as semiconductors or topological materials. The heat transfer pads 304 may be formed with a width that is greater than a width of the source/drain structures of the second components 302.

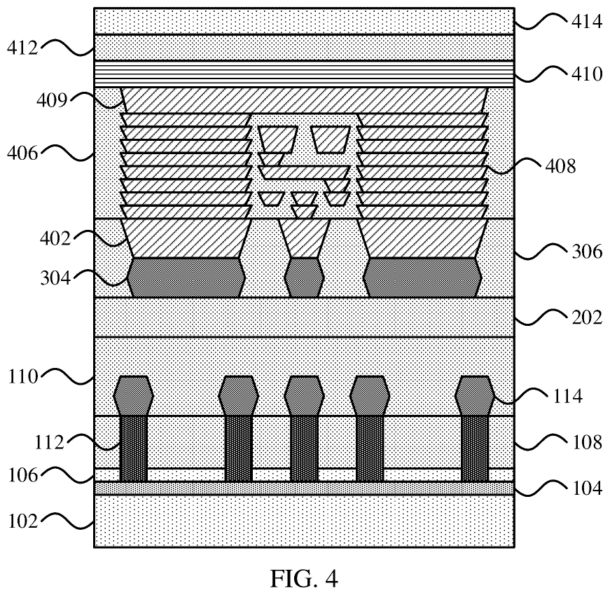

Referring now to FIG. 4, a cross-sectional view of a step in the fabrication of a multi-layer semiconductor device with thermoelectric cooling is shown. Middle-of-line (MOL) contacts 402 are formed by anisotropically etching openings into the interlayer dielectric 306 to expose the heat transfer pads 304. Conductive material is deposited in the openings using any appropriate deposition process and is polished back to the level of the interlayer dielectric 306 using, e.g., a chemical mechanical planarization (CMP) process.

Any appropriate conductive material can be used to form the MOL contacts 402, such as tungsten, nickel, titanium, molybdenum, tantalum, copper, platinum, silver, gold, ruthenium, iridium, rhenium, rhodium, cobalt, and alloys thereof. CMP is performed using, e.g., a chemical or granular slurry and mechanical force to gradually remove upper layers of the device. The slurry may be formulated to be unable to dissolve, for example, the interlayer dielectric 306, resulting in the CMP process's inability to proceed any farther than that layer.

A set of BEOL layers 406 are formed over the second device layer. The BEOL layers 406 may be formed by creating a series of dielectric layers, etching trenches into the dielectric layers, and filling the trenches with conductive material. Vias and interconnects may be formed in this fashion, providing electrical connections to the second components 302. In addition, heat transfer structures 408 are formed by forming vertically adjacent conductive structures in successive BEOL layers. These heat transfer structures 408 provide a thermally conductive pathway between the heat transfer pads 304 and a cooling plate 409 that collects heat generated in the second device layer. Additional BEOL layers 410 may be formed over the cooling plate 409. A handler wafer 414 is connected to the device by bonding layer 412 using, e.g., silicon dioxide.

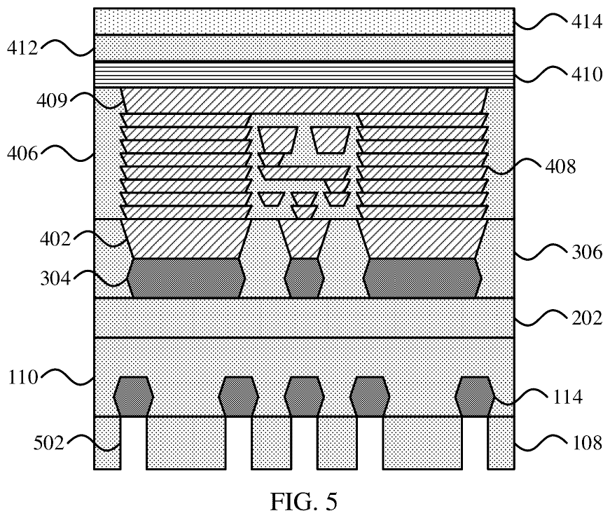

Referring now to FIG. 5, a cross-sectional view of a step in the fabrication of a multi-layer semiconductor device with thermoelectric cooling is shown. The semiconductor substrate 102, the etch stop layer 104, the semiconductor remnant 106, and the placeholder structures 112 are removed in successive selective etches, exposing an underside of the first components 114 with openings 502 in the first dielectric layer 108.

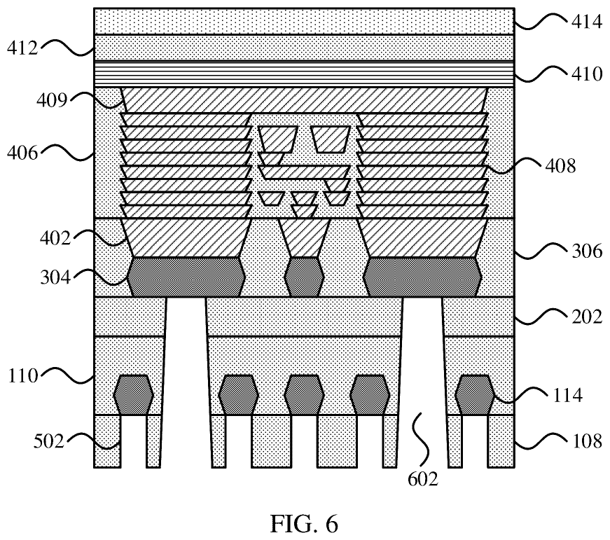

Referring now to FIG. 6, a cross-sectional view of a step in the fabrication of a multi-layer semiconductor device with thermoelectric cooling is shown. Openings 602 are formed by etching through first dielectric layer 108, interlayer dielectric 110, and bonding layer 202 to expose an underside of the heat transfer pads 304. These openings 602 may be defined by masking the surrounding areas using a photolithographic process.

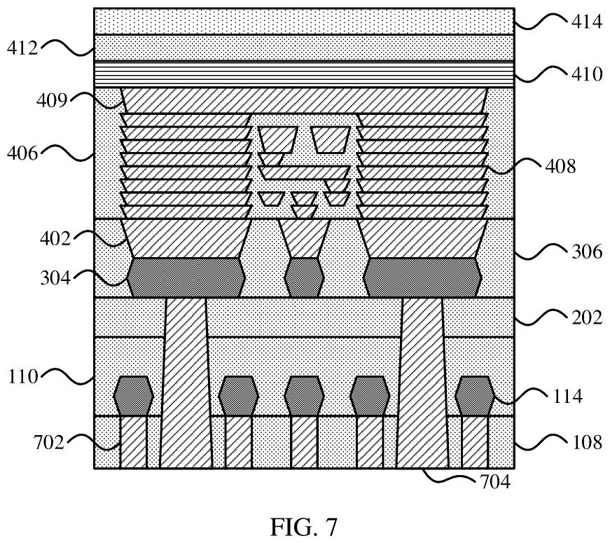

Referring now to FIG. 7, a cross-sectional view of a step in the fabrication of a multi-layer semiconductor device with thermoelectric cooling is shown. Backside contacts 702 and heat transfer vias 704 are formed by depositing a conductive material and removing excess material by a CMP process. In some cases the backside contacts 702 may be formed from a different material than the heat transfer vias 704, for example with the material of the backside contacts being selected for electrical conductivity and the material of the heat transfer vias 704 being selected for heat conductivity. In some cases, copper may be used to achieve both ends.

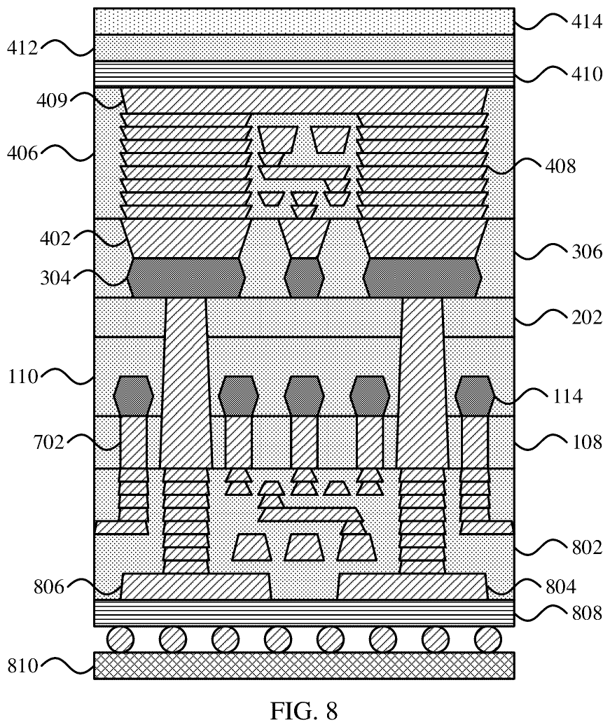

Referring now to FIG. 8, a cross-sectional view of a step in the fabrication of a multi-layer semiconductor device with thermoelectric cooling is shown. Backside power distribution layers 802 are formed on the back side of the device in a manner similar to the BEOL layers 406, with successive layers of dielectric material being etched to form trenches and with the trenches being filled by conductive material. The resulting interconnects may include power sources, for example Vdd 804 and Vss 806. Additional backside power distribution layers 808 may further be formed before being mounted to a cooler 810 by thermally conductive structures, such as solder balls. Thus heat from the front side of the device can travel along heat-conducting structures to the cooler 810 without being trapped. The cooler 810 may be any appropriate passive or active cooling structure, such as a thermoelectric cooler that pumps heat away from the device.

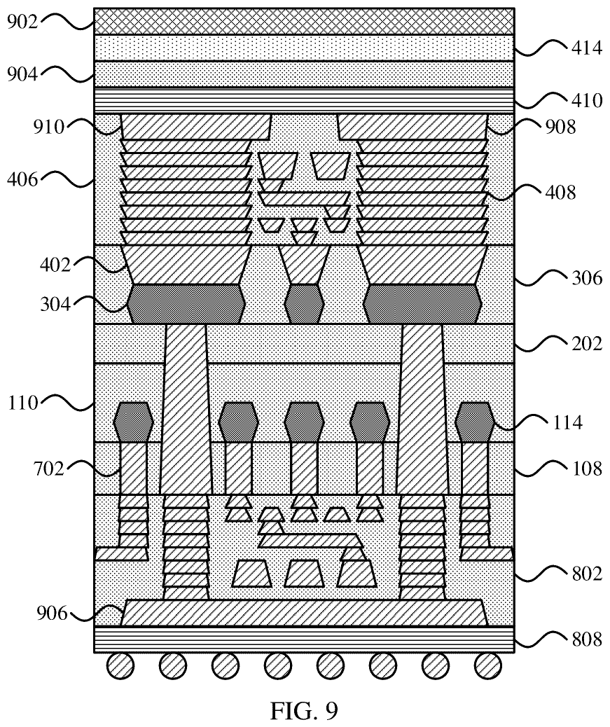

Referring now to FIG. 9, a cross-sectional view of a step in the fabrication of a multi-layer semiconductor device with thermoelectric cooling is shown. The cooler 902 is mounted on the handler wafer 414 instead of on the back side of the device. Instead of bonding layer 412, a hybrid bonding layer 904 is used to promote heat transfer to the handler wafer and, thus, to the cooler 902. In such embodiments the cooling plate 906 may be formed on the back side of the device and the power sources Vdd 908 and VSS 910 may be positioned on the front side of the device.

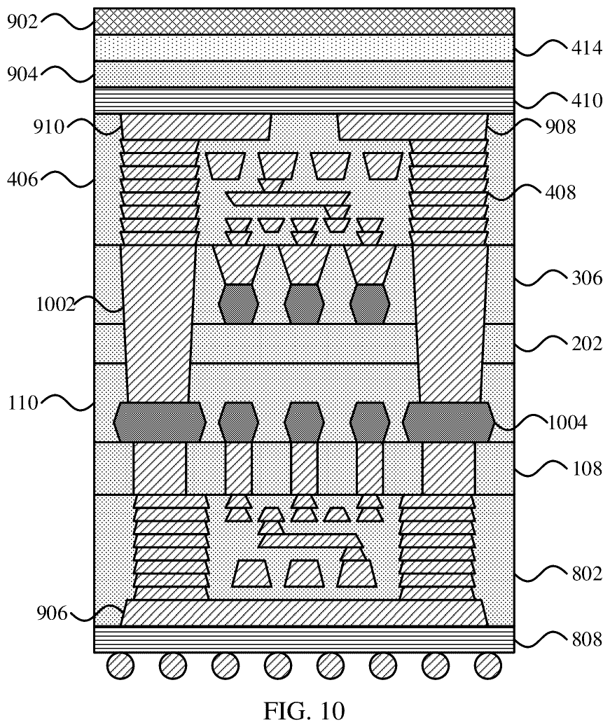

Referring now to FIG. 10, a cross-sectional view of a step in the fabrication of a multi-layer semiconductor device with thermoelectric cooling is shown. In some embodiments the heat transfer pads 1004 may be formed alongside first components 114 in the interlayer dielectric 110. In such embodiments, during the formation of the MOL contacts 402, the thermal vias 1002 may be formed that penetrate through the layers to reach to the heat transfer pads 1004.

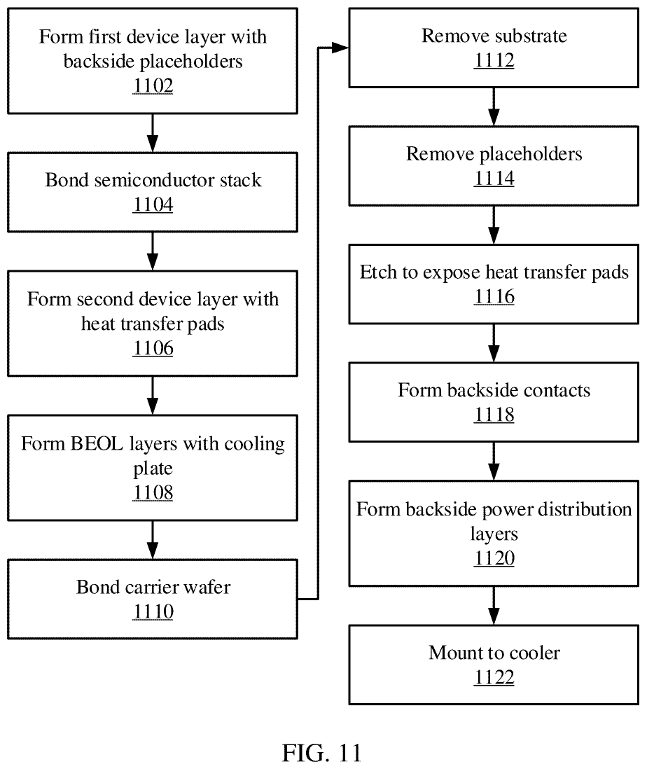

Referring now to FIG. 11, a method of forming a semiconductor device is shown, for an embodiment with a cooling plate 409 in the BEOL layers 406. Block 1102 forms the first device layer with first components 114 and placeholder structures 112 on a semiconductor substrate 102. The first components 114 may include any appropriate active or passive circuit components. The placeholder structures 112 are formed from a material that is selectively etchable with respect to the first components 114 and to a surrounding first dielectric layer 108.

Block 1104 bonds a semiconductor stack, for example including channel layers 206 and sacrificial layers 204, to the first device layer using a bonding layer 202. Block 1106 forms a second device layer with the second components 302 and the heat transfer pads 304. The heat transfer pads 304 may be formed in the same process that forms source/drain structures of the second components 302, but may be wider than those source/drain structures.

Block 1108 forms BEOL layers 406 that include a cooling plate 409, along with any additional BEOL layers 410 that may be needed on top of the cooling plate 409. The BEOL layers 406 include heat transfer structures 408 that connect the cooling plate 409 through the BEOL layers 406 to the heat transfer pads 304. Block 1110 then bonds a handler wafer 414 to the additional BEOL layers 410 using a bonding layer 412.

Block 1112 removes the semiconductor substrate 102, along with etch stop layer 104 and semiconductor remnant 106. Block 1114 selectively etches away the placeholder structures 112 to expose undersides of the first components 114. Block 1116 then etches through the first dielectric layer 108, the interlayer dielectric 110, and the bonding layer 202 to expose the undersides of the heat transfer pads 304.

Block 1118 forms backside contacts 702 and heat transfer vias 704 by depositing conductive material and polishing it back to the level of the first dielectric layer 108. Block 1120 forms backside power distribution layers 802 on the back side of the device, including the power sources Vdd 908 and VSS 910 and any appropriate interconnects that provide thermal conductivity from the heat transfer vias 704. Block 1122 mounts the device to a cooler 810. In some embodiments this mounting may be accomplished by, e.g., forming heat-conducting balls (e.g., solder balls) between the backside power distribution layers 802 and the cooler 810.

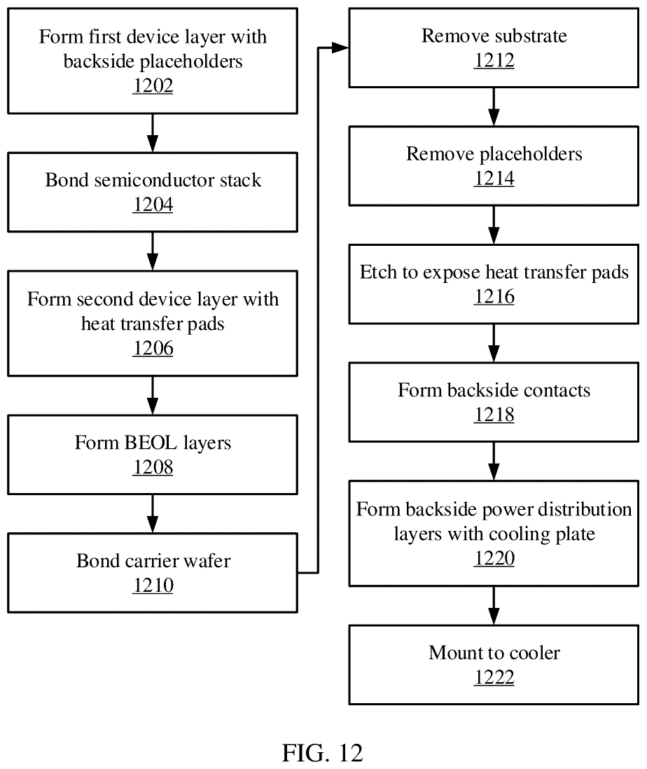

Referring now to FIG. 12, a method of forming a semiconductor device is shown, for an embodiment with a cooling plate 906 in the backside power distribution layers 802. Block 1202 forms the first device layer with first components 114 and placeholder structures 112 on a semiconductor substrate 102. The first components 114 may include any appropriate active or passive circuit components. The placeholder structures 112 are formed from a material that is selectively etchable with respect to the first components 114 and a surrounding first dielectric layer 108.

Block 1204 bonds a semiconductor stack, for example including channel layers 206 and sacrificial layers 204, to the first device layer using a bonding layer 202. Block 1206 forms a second device layer with second components 302 and heat transfer pads 304. The heat transfer pads 304 may be formed in the same process that forms source/drain structures of the second components 302, but may be wider than those source/drain structures.

Block 1208 forms BEOL layers 406, including the power sources Vdd 908 and VSS 910, along with any additional BEOL layers 410 that may be needed on top of the cooling plate 409. The BEOL layers 406 include heat transfer structures 408 that connect the cooling plate 409 through the BEOL layers 406 to the heat transfer pads 304. Block 1210 then bonds a handler wafer 414 to the additional BEOL layers 410 using a bonding layer 412.

Block 1212 removes the semiconductor substrate 102, along with etch stop layer 104 and semiconductor remnant 106. Block 1214 selectively etches away the placeholder structures 112 to expose undersides of the first components 114. Block 1216 then etches through the first dielectric layer 108, the interlayer dielectric 110, and the bonding layer 202 to expose the undersides of the heat transfer pads 304.

Block 1218 forms backside contacts 702 and heat transfer vias 704 by depositing conductive material and polishing it back to the level of the first dielectric layer 108. Block 1220 forms backside power distribution layers 802 on the back side of the device, including cooling plate 906 any appropriate interconnects that provide thermal conductivity to the heat transfer vias 704. Block 1222 mounts the device to a cooler 902. This mounting may be accomplished by, e.g., mounting the cooler 902 to the handler wafer 414 on the front side of the device.

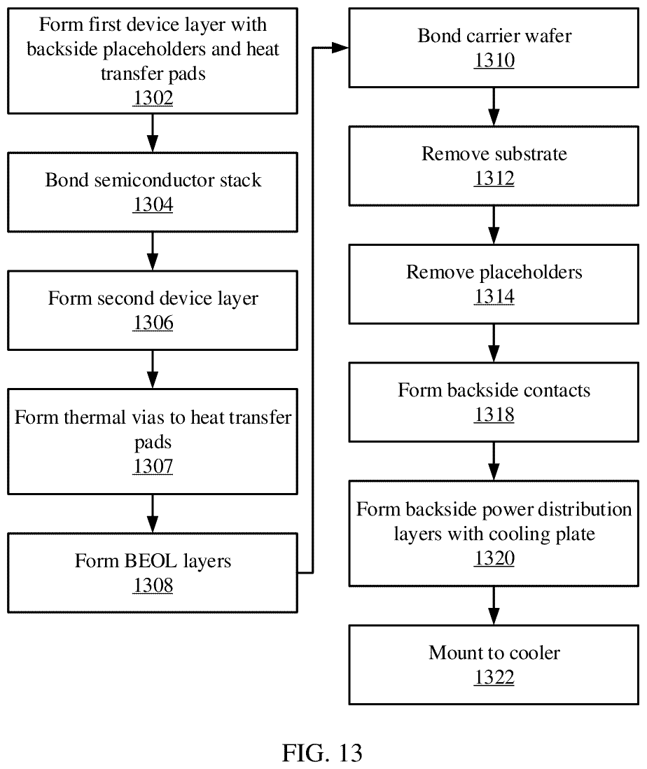

Referring now to FIG. 13, a method of forming a semiconductor device is shown, for an embodiment with heat transfer pads 1004 in the first device layer instead of the second device layer. Block 1302 forms the first device layer with first components 114, heat transfer pads 1004, and placeholder structures 112 on a semiconductor substrate 102. The heat transfer pads 1004 may be formed in the same process that forms source/drain structures of the second components 302, but may be wider than those source/drain structures.

The first components 114 may include any appropriate active or passive circuit components. The placeholder structures 112 are formed from a material that is selectively etchable with respect to the first components 114 and a surrounding first dielectric layer 108.

Block 1304 bonds a semiconductor stack, for example including channel layers 206 and sacrificial layers 204, to the first device layer using a bonding layer 202. Block 1306 forms a second device layer with second components 302. Block 1307 forms thermal vias 1002 through the interlayer dielectric 110, the bonding layer 202, and the interlayer dielectric 306 to make thermal contact with the heat transfer pads 1004.

Block 1308 forms BEOL layers 406, including the power sources Vdd 908 and VSS 910, along with any additional BEOL layers 410 that may be needed on top of the cooling plate 409. The BEOL layers 406 include heat transfer structures 408 that connect through the BEOL layers 406 to thermal vias 1002. Block 1310 then bonds a handler wafer 414 to the additional BEOL layers 410 using a bonding layer 412.

Block 1312 removes the semiconductor substrate 102, along with etch stop layer 104 and semiconductor remnant 106. Block 1314 selectively etches away the placeholder structures 112 to expose undersides of the first components 114 and the heat transfer pads 1004.

Block 1318 forms backside contacts and heat transfer vias by depositing conductive material and polishing it back to the level of the first dielectric layer 108. Block 1320 forms backside power distribution layers 802 on the back side of the device, including cooling plate 906 any appropriate interconnects that provide thermal conductivity to the heat transfer vias. Block 1322 mounts the device to a cooler 902. This mounting may be accomplished by, e.g., mounting the cooler 902 to the handler wafer 414 on the front side of the device.

It is to be understood that aspects of the present invention will be described in terms of a given illustrative architecture; however, other architectures, structures, substrate materials and process features and steps can be varied within the scope of aspects of the present invention.

It will also be understood that when an element such as a layer, region or substrate is referred to as being “on” or “over” another element, it can be directly on the other element or intervening elements can also be present. In contrast, when an element is referred to as being “directly on” or “directly over” another element, there are no intervening elements present. It will also be understood that when an element is referred to as being “connected” or “coupled” to another element, it can be directly connected or coupled to the other element or intervening elements can be present. In contrast, when an element is referred to as being “directly connected” or “directly coupled” to another element, there are no intervening elements present.

The present embodiments can include a design for an integrated circuit chip, which can be created in a graphical computer programming language, and stored in a computer storage medium (such as a disk, tape, physical hard drive, or virtual hard drive such as in a storage access network). If the designer does not fabricate chips or the photolithographic masks used to fabricate chips, the designer can transmit the resulting design by physical means (e.g., by providing a copy of the storage medium storing the design) or electronically (e.g., through the Internet) to such entities, directly or indirectly. The stored design is then converted into the appropriate format (e.g., GDSII) for the fabrication of photolithographic masks, which typically include multiple copies of the chip design in question that are to be formed on a wafer. The photolithographic masks are utilized to define areas of the wafer (and/or the layers thereon) to be etched or otherwise processed.

Methods as described herein can be used in the fabrication of integrated circuit chips. The resulting integrated circuit chips can be distributed by the fabricator in raw wafer form (that is, as a single wafer that has multiple unpackaged chips), as a bare die, or in a packaged form. In the latter case, the chip is mounted in a single chip package (such as a plastic carrier, with leads that are affixed to a motherboard or other higher level carrier) or in a multichip package (such as a ceramic carrier that has either or both surface interconnections or buried interconnections). In any case, the chip is then integrated with other chips, discrete circuit elements, and/or other signal processing devices as part of either (a) an intermediate product, such as a motherboard, or (b) an end product. The end product can be any product that includes integrated circuit chips, ranging from toys and other low-end applications to advanced computer products having a display, a keyboard or other input device, and a central processor.

It should also be understood that material compounds will be described in terms of listed elements, e.g., SiGe. These compounds include different proportions of the elements within the compound, e.g., SiGe includes SiₓGe₁₋ₓ where x is less than or equal to 1, etc. In addition, other elements can be included in the compound and still function in accordance with the present principles. The compounds with additional elements will be referred to herein as alloys.

Reference in the specification to “one embodiment” or “an embodiment”, as well as other variations thereof, means that a particular feature, structure, characteristic, and so forth described in connection with the embodiment is included in at least one embodiment. Thus, the appearances of the phrase “in one embodiment” or “in an embodiment”, as well any other variations, appearing in various places throughout the specification are not necessarily all referring to the same embodiment.

It is to be appreciated that the use of any of the following “/”, “and/or”, and “at least one of”, for example, in the cases of “A/B”, “A and/or B” and “at least one of A and B”, is intended to encompass the selection of the first listed option (A) only, or the selection of the second listed option (B) only, or the selection of both options (A and B). As a further example, in the cases of “A, B, and/or C” and “at least one of A, B, and C”, such phrasing is intended to encompass the selection of the first listed option (A) only, or the selection of the second listed option (B) only, or the selection of the third listed option (C) only, or the selection of the first and the second listed options (A and B) only, or the selection of the first and third listed options (A and C) only, or the selection of the second and third listed options (B and C) only, or the selection of all three options (A and B and C). This can be extended, as readily apparent by one of ordinary skill in this and related arts, for as many items listed.

The terminology used herein is for the purpose of describing particular embodiments only and is not intended to be limiting of example embodiments. As used herein, the singular forms “a,” “an” and “the” are intended to include the plural forms as well, unless the context clearly indicates otherwise. It will be further understood that the terms “comprises,” “comprising,” “includes” and/or “including,” when used herein, specify the presence of stated features, integers, steps, operations, elements and/or components, but do not preclude the presence or addition of one or more other features, integers, steps, operations, elements, components and/or groups thereof.

Spatially relative terms, such as “beneath,” “below,” “lower,” “above,” “upper,” and the like, can be used herein for ease of description to describe one element's or feature's relationship to another element(s) or feature(s) as illustrated in the FIGS. It will be understood that the spatially relative terms are intended to encompass different orientations of the device in use or operation in addition to the orientation depicted in the FIGS. For example, if the device in the FIGS. is turned over, elements described as “below” or “beneath” other elements or features would then be oriented “above” the other elements or features. Thus, the term “below” can encompass both an orientation of above and below. The device can be otherwise oriented (rotated 90 degrees or at other orientations), and the spatially relative descriptors used herein can be interpreted accordingly. In addition, it will also be understood that when a layer is referred to as being “between” two layers, it can be the only layer between the two layers, or one or more intervening layers can also be present.

It will be understood that, although the terms first, second, etc. can be used herein to describe various elements, these elements should not be limited by these terms. These terms are only used to distinguish one element from another element. Thus, a first element discussed below could be termed a second element without departing from the scope of the present concept.

The flowchart and block diagrams in the Figures illustrate the architecture, functionality, and operation of possible implementations of systems, methods, and computer program products according to various embodiments of the present invention. In this regard, each block in the flowchart or block diagrams may represent a module, segment, or portion of instructions, which comprises one or more executable instructions for implementing the specified logical function(s). In some alternative implementations, the functions noted in the blocks may occur out of the order noted in the Figures. For example, two blocks shown in succession may, in fact, be accomplished as one step, executed concurrently, substantially concurrently, in a partially or wholly temporally overlapping manner, or the blocks may sometimes be executed in the reverse order, depending upon the functionality involved. It will also be noted that each block of the block diagrams and/or flowchart illustration, and combinations of blocks in the block diagrams and/or flowchart illustration, can be implemented by special purpose hardware-based systems that perform the specified functions or acts or carry out combinations of special purpose hardware and computer instructions.

Having described preferred embodiments of stacked FETs with thermoelectric cooling (which are intended to be illustrative and not limiting), it is noted that modifications and variations can be made by persons skilled in the art in light of the above teachings. It is therefore to be understood that changes may be made in the particular embodiments disclosed which are within the scope of the invention as outlined by the appended claims. Having thus described aspects of the invention, with the details and particularity required by the patent laws, what is claimed and desired protected by Letters Patent is set forth in the appended claims.

1. A semiconductor device, comprising:
a first device layer comprising thermal vias;
a second device layer over the first device layer having heat transfer pads of semiconductor materials with different doping types in contact with the thermal vias;
a back-end-of-line (BEOL) layer over the second device layer wherein the backside power distribution layer comprises a cooling plate and heat transfer structures that connect the heat transfer pads to the cooling plate;
a backside power distribution layer under the first device layer; and
a cooler mounted to the backside power distribution layer.

2. The semiconductor device of claim 1, wherein the backside power distribution layer includes a power source that connects to the thermal vias by a heat conducting structure.

3. The semiconductor device of claim 1, wherein the first device layer is bonded to the second device layer by a bonding layer and wherein the thermal vias penetrate the bonding layer.

4. The semiconductor device of claim 1, wherein at least one of the heat transfer pads comprises an n-doped semiconductor material and wherein at least one of the heat transfer pads comprises a p-doped semiconductor material.

5. The semiconductor device of claim 1, wherein the second device layer includes a field effect transistor and wherein the heat transfer pads are wider than a source/drain structure of the field effect transistor.

6. The semiconductor device of claim 1, wherein the cooler is an external cooler that is mounted to the backside power distribution layer by solder balls.

7. The semiconductor device of claim 1, wherein the thermal vias extend below the first device layer and contacts the backside power distribution layer.

8. A semiconductor device, comprising:
a first device layer comprising thermal vias;
a second device layer over the first device layer having heat transfer pads of different doping types in contact with the thermal vias;
a back-end-of-line (BEOL) layer over the second device layer;
a backside power distribution layer under the first device layer wherein the backside power distribution layer comprises a cooling plate and a heat transfer structure that connects the thermal vias to the cooling plate; and
a cooler mounted to the BEOL layer.

9. The semiconductor device of claim 8, wherein the BEOL layer includes a power source that connects to the heat transfer pads by a heat conducting structure.

10. The semiconductor device of claim 8, wherein the first device layer is bonded to the second device layer by a bonding layer and wherein the thermal vias penetrate the bonding layer.

11. The semiconductor device of claim 8, wherein at least one of the heat transfer pads comprises an n-doped semiconductor material and wherein at least one of the heat transfer pads comprises a p-doped semiconductor material.

12. The semiconductor device of claim 8, wherein the second device layer includes a field effect transistor and wherein the heat transfer pads are wider than a source/drain structure of the field effect transistor.

13. The semiconductor device of claim 8, wherein the cooler is an external cooler that is mounted to a handler wafer on the BEOL layer.

14. The semiconductor device of claim 8, wherein the thermal vias extend below the first device layer and contacts the backside power distribution layer.

15. A semiconductor device, comprising:
a first device layer comprising heat transfer pads;
a second device layer over the first device layer having thermal vias in contact with the heat transfer pads;
a back-end-of-line (BEOL) layer over the second device layer;
a backside power distribution layer under the first device layer, wherein the backside power distribution layer comprises a cooling plate and heat transfer structures that connect the heat transfer pads to the cooling plate; and
a cooler mounted to the BEOL layer.

16. The semiconductor device of claim 15, wherein the BEOL layer includes a power source that connects to the heat transfer pads by a heat conducting structure.

17. The semiconductor device of claim 15, wherein the first device layer is bonded to the second device layer by a bonding layer and wherein the thermal vias penetrate the bonding layer.

18. The semiconductor device of claim 15, wherein at least one of the heat transfer pads comprises an n-doped semiconductor material and wherein at least one of the heat transfer pads comprises a p-doped semiconductor material.

19. The semiconductor device of claim 15, wherein the second device layer includes a field effect transistor and wherein the heat transfer pads are wider than a source/drain structure of the field effect transistor.

20. The semiconductor device of claim 15, wherein the cooler is an external cooler that is mounted to a handler wafer on the BEOL layer.
